(19) United States
(12) Patent Application Publication
(10) Pub. No.: US 2013/0269740 A1
(43) Pub. Date: Oct. 17, 2013

(54) THERMOELECTRIC GENERATOR

(71) Applicants: Peter Gröppel, Erlangen (DE); Steffen Lang, Erlangen (DE); Eberhard Ritzhaupt-Kleissl, Balersdorf (DE)

(72) Inventors: Peter Gröppel, Erlangen (DE); Steffen Lang, Erlangen (DE); Eberhard Ritzhaupt-Kleissl, Balersdorf (DE)

(73) Assignee: SIEMENS AKTIENGESELLSCHAFT, Munich (DE)

(21) Appl. No.: 13/876,942

(22) PCT Filed: Sep. 5, 2011
(86) PCT No.: PCT/EP11/65279

§ 371 Date: Jun. 24, 2013

(30) Foreign Application Priority Data
Sep. 29, 2010 (DE) 10 2010 041 652.5

(51) Int. Cl. H01L 35/32

(52) U.S. Cl. CPC H01L 35/32
USPC 136/205

(57) ABSTRACT

A thermoelectric generator utilizes the waste heat of exhaust gases having a temperature of less than 250° C., such as those resulting from the operation of power plants. In this case, partially conductive or semiconductive particles are used which are arranged in layers between hot and cold air channels and produce a usable current flow.

### CROSS REFERENCE TO RELATED APPLICATIONS

This application is based on and hereby claims priority to International Application No. PCT/EP2011/065279 filed on Sep. 5, 2011 and German Application No. 10 2010 041 652.5 filed on Sep. 29, 2010, the contents of which are hereby incorporated by reference.

### BACKGROUND

The invention relates to a thermoelectric generator.

Thus, for example, an 800 MW coal-fired power station emits three million cubic meters of exhaust gas per hour at a temperature of less than 250° C. (approximately 150° C.).

Parts of that energy are to be rendered capable of being utilized by thermoelectric generators (TEG) so that the greenhouse gas emissions produced in the burning of fossil fuels can be used in order to curtail greenhouse gases elsewhere, thereby satisfying the increasing requirements in respect of environmental and climate protection. Toward that end the waste heat from combustion processes in, for example, industrial facilities, automobiles, and private households, etc. is converted into electrical energy with the aid of a thermoelectric generator and so will be available for further use as an energy source.

There are thermoelectric generators, alternators for example, in cars. In industrial facilities and private households, too, increasing attempts are being made to render unutilized waste heat capable of being utilized with the aid of thermoelectric generators and to establish it as a secondary energy source.

Existing thermoelectric generators have a specific number of thermal legs that have a certain surface area and are usually made of intermetallic materials. In this case the thermoelectric generators are usually constructed in the form of cascaded individual modules.

For example nanometer-thin layers of thermoelectrically differently active material are therein laid one upon the other.

For the necessary cascading of thermoelectric elements the Freiburg-based company Micropelt has reduced the size of the individual elements and as a result is already able to achieve a high voltage yield per unit area. Other thermoelectric generators are known from the company EnOcean in Oberhaching and from the Fraunhofer Institute in Erlangen.

Apart from their design, a continuing problematic aspect with regard to the thermoelectric generators constructed in the related art is also that materials which exhibit a high degree of thermoelectric conversion efficiency usually have extremely toxic constituents such as arsenic, thallium or lead telluride, and/or components that are very expensive such as platinum.

### SUMMARY

There is therefore still the need to create novel thermoelectric generators that overcome the disadvantages of the related art in terms both of the layout and circuitry of their modules and of the material used.

One potential object is accordingly to provide a thermoelectric generator which has a high energy density while being of compact design, can be as flexible as possible in its structure in terms of the layout and/or circuitry of its modules, and can be produced economically and on a scale suitable for mass production using non-toxic materials as far as possible.

The inventors propose a thermoelectric generator comprising one or more stacks formed from horizontally arranged layers having channels extending vertically therebetween, wherein the layers are a sequence of a p-type semiconducting and an n-type semiconducting layer with an insulating layer sandwiched therebetween, wherein in each case two successive semiconducting layers are electrically connected across the insulating layer so that a current flow due to thermal diffusion takes place only in the horizontal direction along the temperature gradient inside a semiconducting layer, wherein the vertically extending channels duct warm and cold air alternately with the result that a temperature gradient is produced inside the semiconducting layers.

According to an advantageous embodiment variant the semiconducting layers include a support matrix incorporated into which are particles, preferably platelet-like particles such as mica, which effect the semiconducting property of the layer. The layer is then produced using, for example, the thick-film technique.

The particles are formed of, for example, a ceramic material coated so as to be semiconducting.

The particles are formed of, for example, mica or an oxidic material having low thermal conductivity.

Said particles are then coated with a semiconducting oxide mixture so that incorporating them into a support matrix will cause it to exhibit n-type or p-type conductivity. Using oxidic semiconductor materials in thermoelectric generators will improve the efficiency and environmental compatibility of these systems.

According to a preferred embodiment variant, in order to produce a layer the support matrix having semiconducting particles is applied as a coating to a substrate such as a foil, fabric, a tape and/or ceramic substrates.

The individual layers in the layer structure have, for example, a layer thickness less than 300 μm.

According to another embodiment variant the particles are present in the support matrix in a multimodal distribution having different sizes and/or shapes.

According to a preferred embodiment variant the particles have a large aspect ratio; they are present preferably in platelet-like form.

The particles from partially conductive materials are for example particles based on oxide ceramics, especially doped oxide ceramics, which are suitable on account of their high electrical conductivity and/or low thermal conductivity.

A structure according to the proposals is formed from, for example, coated planar materials as substrates (layer thickness of a single layer less than 300 micrometers, for instance) has an electrical potential because the necessary contacting of the conductive layers can be by vias (via=vertical interconnect access), as a result of which throughflow channels for the hot gases will be simultaneously produced. Said flow channels can be designed in terms of their shape and dimensions such that the energy available in the heated air current will be efficiently conveyed to the TEG.

Resins in general, especially epoxy resins, varnishes and/or tapes, serve for example as the support matrix.

When the coated particles are incorporated into the support matrix, a solvent is preferably added thereto, as a result of which convection currents by which the particles in the support matrix will become oriented will form therein as the solvent evaporates. This advantageously results in optimal contacting of the particles among themselves. Furthermore, an undesirable sedimenting of the particles in the support matrix is avoided as a result of the particles' planar geometry.

It is furthermore preferred for the particle-mass concentration of the particles in the support matrix to be selected such that the layer material is above the percolation threshold.

It is preferred in this case for the particle-mass concentration of the particles to be more than 25 wt %. Upward of that specific particle-mass concentration in the support matrix the layer material will be above the percolation threshold and the surface resistance of the layer material will barely change as the particle-mass concentration increases. The layer material will consequently scarcely be subject to variations in surface resistance, which can be well reproduced as a result.

The particles are preferably formed of mica, silicon carbide or a non-doped metal oxide, especially aluminum oxide. Improved contacting of the partially conducting particles among themselves will be achieved owing to the particles' planar structure. The metal oxide that coats the particles is selected preferably from the following group: metal oxide in a binary and ternary mixing phase, in particular tin oxide, zinc oxide, zinc stannate, titanium oxide, lead oxide and silicon carbide. An element from the group comprising antimony, indium and cadmium is preferably selected as the doping element for the n-type.

Owing to their large aspect ratio across a comparatively large concentration range the platelet-shaped partially conducting particles result in percolation so that it is possible with the aid of the coatings to set the conductivities necessary for a large thermoelectric effect for n-type and p-type semiconductors or partial conductors.

Alongside their shape, the particles' coating is of crucial significance to electrical conductivity. A defined setting of the electrical conductivity will be possible by precisely applying the doped metal oxides and through their doping.

The Result is a Number of Technical Advantages:

Good separation between electrical conductivity (high) and thermal conductivity (low) as is the aim for thermoelectric generators, coupled with a high degree of design freedom.

A thermoelectric generator having an open-circuit voltage capable of being commercially utilized can be produced by a thermal parallel connection and an electrical serial connection of the individual modules.

An improvement in the form factor is achieved because oxidic semiconductors that have been embedded in a support matrix are applied as a coating to insulating planar materials, resulting in degrees of freedom in the production of corresponding systems.

Finally the temperature gradients will be efficiently set because of large surfaces, for example using porous ceramic materials.

According to the proposals there will be simple electrical cascading of individual modules through the use of laminating technologies.

A high level of economic efficiency will be achieved on account of low material costs and from using commercially available substrate materials.

What is envisaged, for instance, is the use of nano-coating technologies for efficient deposition of the oxidic semiconductor materials.

Sintered ceramic materials have for decades formed the basis of catalytic converters (in motor vehicles).

One advantage is the application of p-type and n-type semiconductor structures and/or coatings in a support matrix for low-temperature applications (<250° C.).

The listed success factors in combination will enable TEGs to be economically employed also at low temperatures (<250° C.) as typically occur in flue-gas chimneys.

The oxidic materials of the semiconducting layers are preferably oxide mixtures. Listed by way of example in Table 1 are different types and compositions of semiconducting or partially conducting oxide mixtures.

TABLE 1
Selection of various compositions of semiconducting or partially
conducting oxide mixtures for thermoelectric generators.

| p-type | n-type |
|---|---|
| (Ca_{2.8}Co₄Na_{0.2}Oₓ) | (La₁₋ₓSrₓ)FeO₃ |
| (Bi_{0.3}Ca_{3.4}Co₄Oₓ) | Ca₁₋ₓMₓMnO₃ |
| (Ca_{3.4}Co₄Na_{0.2}Oₓ) | ZnO/In₂O₃ |
| (Bi_{0.3}Ca_{2.8}Co₄Oₓ) | (ZnO)ₘIn₂O₃ |
| (CoNi)As₃) | CuFe₁₋ₓNiₓO₂ |
| Ca₂Co₂O₅ | (CoNi)As₃) |
| Ca₃Co₄O₉ | (YbFe₂O₄ |
| Bi₂Sr₂₋ₓLaₓCo₂O₉ | Sb-doped SnO₂ |
| Bi_{2-y}Sn_{y}Sr₂Co₂O₉ | Titanates |
| | Stannates |

Known further are p-type conducting cuprites such as CuAlO₂, CuCrO₂ and CuCr₁₋ₓAlₓO₂ or other copper compounds such as CuSCN which come into consideration as partially conducting materials.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 is a schematic side view of a TEG including individual modules based on semiconducting or partially conducting and insulating layers,

FIG. 2 is a plan view onto a TEG having a layered structure and round vias,

FIG. 3 is another plan view onto a TEG having a layered structure and slot-shaped vias,

FIG. 4 is a schematic side view of a TEG module having a slot-shaped channel geometry, and

FIG. 5 is a schematic side view of a TEG in which the semiconducting or partially conducting layers have been applied using the doctor-blade technique.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

FIG. 1 is a schematic side view of a thermoelectric generator (TEG). To be seen are two blocks 1 and 2 that include individual layers 8 to 10 and on whose sides are located three channels through which air flows, wherein the outer channels 3 duct cold air and the inner channel 4 ducts warm air. The electrical vias 6 and 7 are located in the channels 3, 4. For example, warm air flows through the channel 4 and cold air through the channels 3 during operation. As a result, charge carriers, that is to say for example electrons, in the p-type doped layer 8 migrate within it along the temperature gradient from cold to warm, in the example shown, therefore, away from the channels 3 toward the center in the direction of channel 4.

Extending across the entire area beneath the p-type doped layer 8 is the insulating layer 9 in which no migration of charge carriers takes place. Beneath the insulating layer 9 is the n-doped layer 10 within which a charge carrier migration likewise takes place, though in the opposite direction from warm to cold.

The two blocks have the same structure and for example the same layers 8, 9, or 10 are located on one plane. This may also have been resolved differently in individual cases. Routed separately from each other, the electrical vias 6 and 7 connect the n-type doped layer 10 to the p-type doped layer 8 in the warm region on the one hand and, on the other hand, the same, for example n-type doped, layer 10 to the next higher or next lower p-type doped layer 8 in the cold region. Current will thus be able to flow through the individual modules.

The individual layers 8 to 10 are preferably extremely thin layers having a thickness of, for example, less than 300 micrometers.

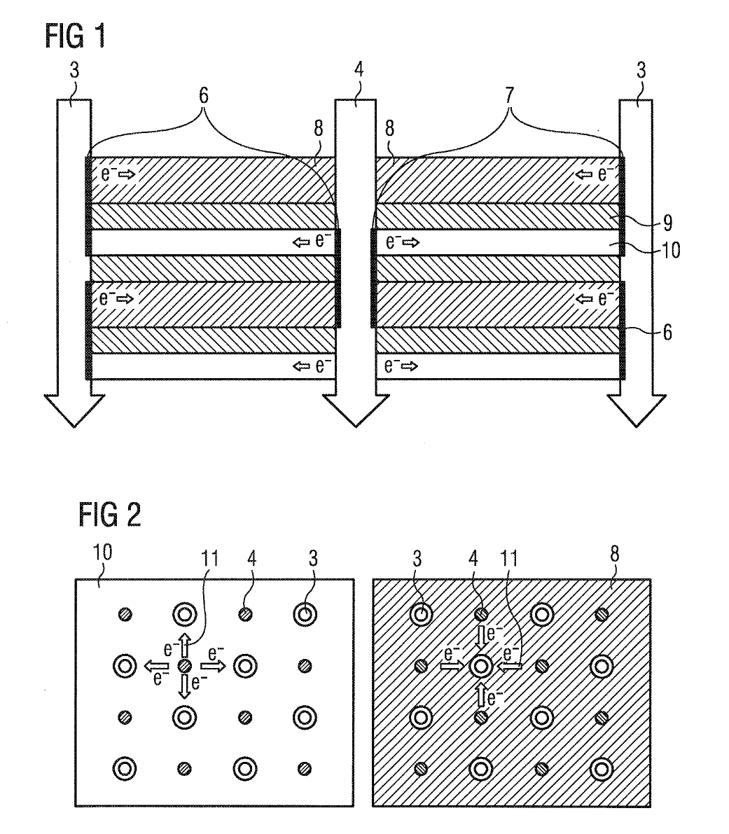

FIG. 2 is a plan view onto the individual layers, onto an n-doped layer 10 on the left, and onto a p-type doped layer 8 on the right. Shown within the layer are the channels 3, 4 and other channels which are not visible in FIG. 1 since that figure shows a detail of a side view.

Indicated by arrows 11 within the n-doped layer 10 (shown on the left in FIG. 2) is the migration of the charge carriers within the layer from warm, meaning from the region around warm-air ducting channel 4, to cold, meaning the regions around cold-air channels 3. The cross-sections of channels 3 are embodied here as round by way of example.

Indicated by arrows 11 within the p-type doped layer 8 (shown on the right in FIG. 2) is the migration of the charge carriers from cold, meaning from the region around cold-air channels 3, to warm, meaning the region around warm-air channels 4. Voltage generation will accordingly take place here owing to the flow channels to which different temperatures are being applied.

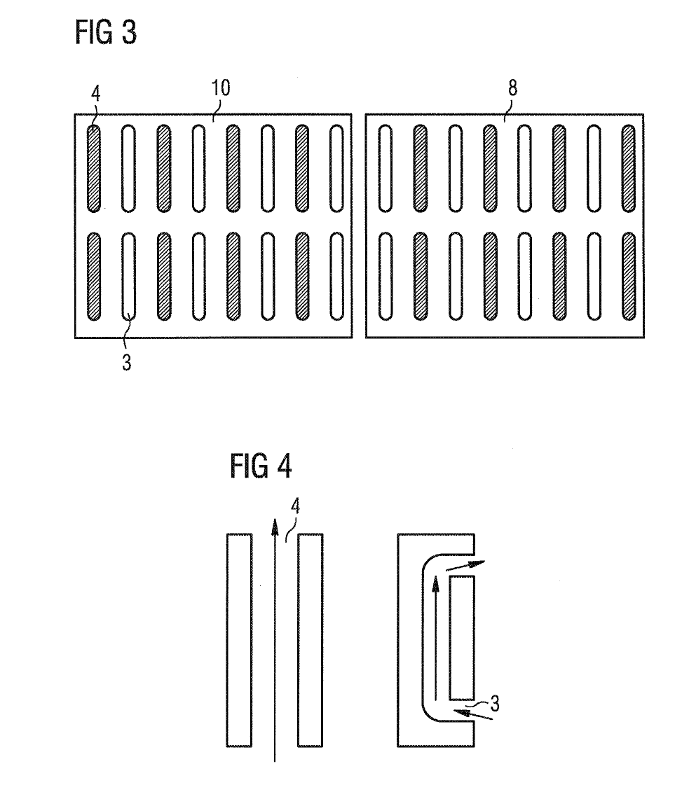

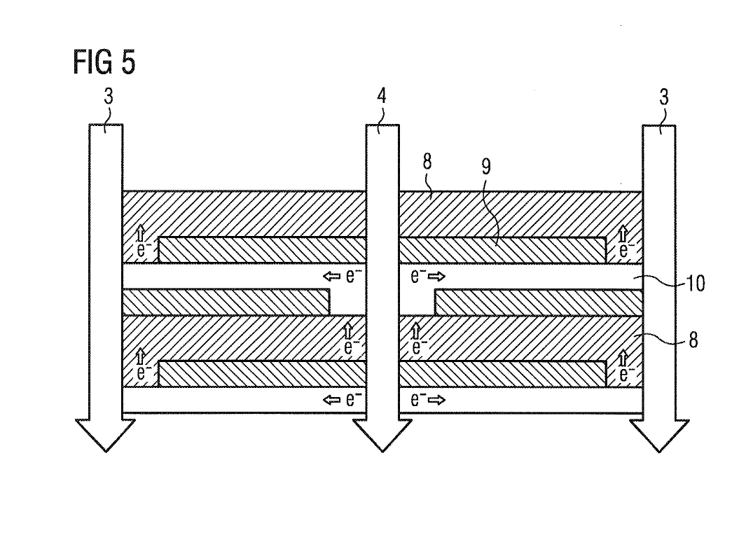

The flow channels 3, 4 can furthermore not just have round geometries but can also be, for example, slot-shaped as shown schematically in FIGS. 3 and 4. It is particularly advantageous here that the stack effect is exploited in cold-air channels 3, 4 in order to draw fresh cooling air into the TEG modules. In this case heated cold air exits the channels at the top and in so doing draws fresh cold air into the system from below.

FIG. 3 is a plan view comparable with FIG. 2, wherein slot-shaped flow channels 3 and 4 are again arranged alternately in the layer. For clarity of illustration reasons, the arrows 11 which in the left-hand n-doped layer 10 always indicate a migration from warm channels 4 to cold channels 3 and in the right-hand p-type doped layer 8 indicate a migration in the opposite direction from channels 3 to channels 4 have been omitted.

FIG. 4 is a side view of a detail of a side view shown in FIGS. 1 and 5, wherein slot-shaped channel geometries are shown. Depicted on the left is a hot-air channel 4 and on the right a cold air-channel 3 exhibiting the stack effect.

FIG. 5 is again a side view, comparable with FIG. 1, of an entire module having two blocks 1, 2 including a plurality of layers 8 to 10, although the layer structure is different from that shown in FIG. 1. The individual layers, particularly the semiconductor layers, are here applied using the doctor-blade technique. The electrical vias 6 and 7 can thus be replaced through simple patterning of the insulating layers and subsequent application of a doped layer by a doctor blade such that it will at one point come into direct electrical contact with the nearest oppositely doped layer. In FIG. 5 the passage of the charge carriers, that is to say the electrons for example, is indicated by arrows 11.

The exemplary embodiments shown in the figures illustrate schematically that the semiconducting or partially conducting layers 8 and 10 are separated from each other in the layer structure by electrically insulating layers 9 such that a current flow 11 due to thermal diffusion is possible only in the horizontal direction (along the temperature gradient). The semiconducting or partially conducting layers 8 and 10 are made from planar materials such as foils, fabrics and ceramic substrates, or are realized by thick-film technology. Coated partially conducting particles are employed for that purpose.

In contrast to the related art the modules shown demonstrate a high degree of design freedom and thereby offer the potential to efficiently transfer the energy of a stream of a large volume of waste gas at a temperature in the region of 150° C. to a thermoelectric generator and hence to convert same into electrical energy. Thanks to a thermal parallel connection and an electrical serial connection of the described individual modules it is possible to realize a cost-effective thermoelectric generator having an open-circuit voltage capable of being commercially utilized.

The modules can be produced on the basis of plastic-bonded semiconducting or partially conducting materials. In contrast to metallic materials according to the related art (Bi₂Te₃, PbTe, SiGe, BiSb, . . . ), oxidic semiconductor materials in this case offer major potential insofar as the following aspects are concerned:
Improvement in the thermoelectric figure of merit Z and hence the efficiency of a TEG
Reduction of the thermal conductivity (significantly lower in the case of oxidic ceramics than for metals). Ideal material pairing (ceramic p-type and n-type semiconductors can be tailored to boost the thermoelectric effect).

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-7. (canceled)

8. A thermoelectric generator comprising:
a stack of horizontally arranged layers, the stack comprising a p-type semiconducting layer and an n-type semiconducting layer with an insulating layer sandwiched therebetween;
vertically extending channels extending through the horizontally arranged layers of the stack to produce a temperature gradient inside the semiconducting layers, the channels comprising warm air ducting channels and cold air ducting channels alternately arranged; and
an electrical connection to connect adjacent p-type and n-type semiconducting layers across the insulating layer so that a current flow due to thermal diffusion is possible only in a horizontal direction in a series-connection basis, along the temperature gradient inside the semiconducting layers.

9. The thermoelectric generator as claimed in claim 8, wherein
the thermoelectric generator comprises a plurality of p-type semiconducting layers, a plurality of n-type semiconducting layers and a plurality of insulating layers,
the p-type semiconducting layers and n-type semiconducting layers are alternately arranged with an insulating layer between each adjacent semiconductor layers, and
an electrical connection is provided for all adjacent semiconductor layers.

10. The thermoelectric generator as claimed in claim 8, wherein each semiconducting layer includes a support matrix into which particles coated with a doped oxide are incorporated.

11. The thermoelectric generator as claimed in claim 10, wherein the doped oxide is a mixed oxide.

12. The thermoelectric generator as claimed in claim 10, wherein the particles are platelet-shaped.

13. The thermoelectric generator as claimed in claim 10, wherein the doped oxide coating the particles in the p-type semiconducting layer is at least one oxide selected from the group consisting of Ca_{2.8}Co₄Na_{0.2}Oₓ, Bi_{0.3}Ca_{3.4}Co₄Oₓ, Ca_{3.4}Co₄Na_{0.2}Oₓ, Bi_{0.3}Ca_{2.8}Co₄Oₓ, (CoNi)As₃, Ca₂Co₂O₅, Ca₃Co₄O₉, Bi₂Sr₂₋ₓLaₓCo₂O₉, Bi_{2-y}Sn_{y}Sr₂Co₂O₉, CuAlO₂, CuCrO₂, CuCr₁₋ₓAlₓO₂, and CuSCN.

14. The thermoelectric generator as claimed in claim 10, wherein the doped oxide coating the particles in the n-type semiconducting layer is at least one oxide selected from the group consisting of (La₁₋ₓSrₓ) FeO₃, Ca₁₋ₓMₓMnO₃, ZnO/In₂O₃, (ZnO)ₘIn₂O₃, CuFe₁₋ₓNiₓO₂, (CoNi)As₃, YbFe₂O₄, Sb-doped SnO₂, a titanate and a stannate.

15. The thermoelectric generator as claimed in claim 11, wherein the particles are platelet-shaped.

16. The thermoelectric generator as claimed in claim 15, wherein the doped oxide coating the particles in the p-type semiconducting layer is at least one oxide selected from the group consisting of Ca_{2.8}Co₄Na_{0.2}Oₓ, Bi_{0.3}Ca_{3.4}Co₄Oₓ, Ca_{3.4}Co₄Na_{0.2}Oₓ, Bi_{0.3}Ca_{2.8}CO₄Oₓ, (CoNi)As₃, Ca₂Co₂O₅, Ca₃Co₄O₉, Bi₂Sr₂₋ₓLaₓCo₂O₉, Bi_{2-y}Sn_{y}Sr₂Co₂O₉, CuAIO₂, CuCrO₂, CuCr₁₋ₓAlₓO₂, and CuSCN.

17. The thermoelectric generator as claimed in claim 16, wherein the doped oxide coating the particles in the n-type semiconducting layer is at least one oxide selected from the group consisting of (La₁₋ₓSrₓ) FeO₃, Ca₁₋ₓMₓMnO₃, ZnO/In₂O₃, (ZnO)ₘIn₂O₃, CuFe₁₋ₓNiₓO₂, (CoNi)As₃, YbFe₂O₄, Sb-doped SnO₂, a titanate and a stannate.

18. The thermoelectric generator as claimed in claim 17, wherein
the thermoelectric generator comprises a plurality of p-type semiconducting layers, a plurality of n-type semiconducting layers and a plurality of insulating layers,
the p-type semiconducting layers and n-type semiconducting layers are alternately arranged with an insulating layer between each adjacent semiconductor layers, and
an electrical connection is provided for all adjacent semiconductor layers.

19. A thermoelectric generator comprising:
a layered structure with alternating p-type and n-type semiconducting layers, wherein each semiconducting layer has particles made of a partially conducting material.

20. The thermoelectric generator as claimed in claim 19, wherein each semiconducting layer includes a support matrix into which particles coated with a doped oxide are incorporated.

21. The thermoelectric generator as claimed in claim 20, wherein the doped oxide is a mixed oxide.

22. The thermoelectric generator as claimed in claim 20, wherein the particles are platelet-shaped.

23. The thermoelectric generator as claimed in claim 20, wherein the doped oxide coating the particles in the p-type semiconducting layer is at least one oxide selected from the group consisting of Ca_{2.8}Co₄Na_{0.2}Oₓ, Bi_{0.3}Ca_{3.4}Co₄Oₓ, Ca_{3.4}Co₄Na_{0.2}Oₓ, Bi_{0.3}Ca_{2.8}CO₄Oₓ, (CoNi)As₃, Ca₂Co₂O₅, Ca₃Co₄O₉, Bi₂Sr₂₋ₓLaₓCo₂O₉, Bi_{2-y}Sn_{y}Sr₂Co₂O₉, CuAIO₂, CuCrO₂, CuCr₁₋ₓAlₓO₂, and CuSCN.

24. The thermoelectric generator as claimed in claim 20, wherein the doped oxide coating the particles in the n-type semiconducting layer is at least one oxide selected from the group consisting of (La₁₋ₓSrₓ) FeO₃, Ca₁₋ₓMₓMnO₃, ZnO/In₂O₃, (ZnO)ₘIn₂O₃, CuFe₁₋ₓNiₓO₂, (CoNi)As₃, YbFe₂O₄, Sb-doped SnO₂, a titanate and a stannate.

25. The thermoelectric generator as claimed in claim 21, wherein the particles are platelet-shaped.

26. The thermoelectric generator as claimed in claim 25, wherein the doped oxide coating the particles in the p-type semiconducting layer is at least one oxide selected from the group consisting of Ca_{2.8}Co₄Na_{0.2}Oₓ, Bi_{0.3}Ca_{3.4}Co₄Oₓ, Ca_{3.4}Co₄Na_{0.2}Oₓ, Bi_{0.3}Ca_{2.8}CO₄Oₓ, (CoNi)As₃, Ca₂Co₂O₅, Ca₃Co₄O₉, Bi₂Sr₂₋ₓLaₓCo₂O₉, Bi_{2-y}Sn_{y}Sr₂Co₂O₉, CuAIO₂, CuCrO₂, CuCr₁₋ₓAlₓO₂, and CuSCN.

27. The thermoelectric generator as claimed in claim 26, wherein the doped oxide coating the particles in the n-type semiconducting layer is at least one oxide selected from the group consisting of (La₁₋ₓSrₓ) FeO₃, Ca₁₋ₓMₓMnO₃, ZnO/In₂O₃, (ZnO)ₘIn₂O₃, CuFe₁₋ₓNiₓO₂, (CoNi)As₃, YbFe₂O₄, Sb-doped SnO₂, a titanate and a stannate.
